(19) United States
(12) Patent Application Publication
(10) Pub. No.: US 2015/0380379 A1
(43) Pub. Date: Dec. 31, 2015

(54) SYSTEM AND METHOD FOR THERMO-COMPRESSION BONDING OF HIGH BUMP COUNT SEMICONDUCTORS

(71) Applicant: MRSI Systems, LLC, North Billerica, MA (US)

(72) Inventors: Cyriac Devasia, Nashua, NH (US); Nicholas Samuel Celia, JR., Avon, MA (US)

(21) Appl. No.: 14/752,190

(22) Filed: Jun. 26, 2015

Related U.S. Application Data
(60) Provisional application No. 62/017,434, filed on Jun. 26, 2014.

(51) Int. Cl. H01L 23/00

(52) U.S. Cl. CPC H01L 24/75; H01L 24/81; H01L 2224/7592; H01L 2224/75301; H01L 2224/81203; H01L 2224/81908; H01L 2224/7565; H01L 2924/351; H01L 2224/7525; H01L 2224/7555; H01L 2224/81801

(57) ABSTRACT

A system and method are provided for enabling the production of semiconductors requiring very high precision thermo-compression bonding, the system comprising a thermo-compression bonding system having force and/or distance measuring sensors configured to sense thermal expansion of system components and a controller configured to counteract such expansion by exercising appropriate control over such system. This system and method may be used for both constant force profile applications as well as those requiring variable force during a bonding operation.

### FIELD OF THE INVENTION

The invention relates to semiconductor fabrication, and, more particularly, to a system and method for thermo-compression bonding of die to substrate.

### BACKGROUND OF THE INVENTION

Thermo-compression bonding is a common method of attaching a die to a substrate. A typical thermo-compression bonding system uses two opposing parallel planar surfaces, a die head and a substrate head, to apply heat and pressure to a die and substrate to be bonded. The side of the die to be bonded to the substrate will typically have many small, tear-drop shaped, “bumps” of solder, which are applied in a prior processing step, while the substrate will have “bump pads” applied to the side to be bonded to the die, which are also applied during a prior processing step. Just prior to bonding, the solder bumps and bump pads are carefully aligned. These bump pads engage with the solder bumps during a bonding operation to form an electrical and physical connection between the die and the substrate. Those skilled in the art will recognize that the use of copper pillars (or columns) and micro-bumps with solder caps, typically made of SnAg, although other alloys are possible, rather than pure solder bumps are also known, with the general concept remaining largely the same as with solder bumps.

In a typical thermo-compression bonding operation, the die head is rapidly heated to between 300-450° C. while simultaneously applying compressive forces to the die and substrate package, causing the pre-applied solder bumps to flow and connect the die to the substrate. At the moment of deformation, there is typically intended to be a partial and controlled collapse of the solder bumps.

After the solder bumps have connected the die to substrate, the die head is then cooled to freeze the connections in place. The substrate head also undergoes similar, albeit less extreme, thermal changes (the substrate head may reach temperatures of approximately 150° C. during a thermo-compression bonding operation, as higher temperatures could cause degradation of the substrate, which is generally made of organic materials).

While these techniques have served the industry well for a number of years, existing thermo-compression bonding systems and methods are unable to achieve satisfactory bonding performance and yield when used for bonding the latest generations of dies to substrates. These new generations of dies and substrates utilize an increased number of connections, solder bumps or otherwise, between the die and substrate, typically without a corresponding increase in the size of the die or substrate. In order to allow dies of similar size to accommodate these additional connections, each connection has become smaller. These semiconductor packages are sometimes referred to as “high bump count” packages.

The primary issue is that current systems and methods cannot reliably achieve the level of precision required to ensure that the individual solder bumps do not come into contact with adjacent solder bumps during a bonding operation. Keeping closely spaced solder bumps from contacting adjacent solder bumps is crucial to a thermo-compression bonding operation, as even a single poor connection out of many thousands may cause the entire package to fail to function. This failure is caused by the uncontrolled collapse of these bumps, and it may also cause issues with the later manufacturing process of under filling, where a resin is introduced between the die and substrate, since bridged adjacent solder bumps will limit the ability of the resin to flow between the die and substrate.

This problem is, in part, due to the high temperatures involved in thermo-compression bonding as well as the necessity of rapidly heating and cooling the die and substrate contacting surfaces to facilitate rapid production of semiconductor packages. This rapid heating causes the die and substrate heads to expand. Since the system is not kept at a constant temperature, it does not reach an equilibrium state and thermal expansion and contraction occurs during each bonding operation.

This thermal expansion of the die and substrate heads in thermo-compression bonding systems has been known for some time, but has been regarded as too insignificant to affect the thermo-compression bonding operation. The very latest dies, however, have reached a point where this thermal expansion does not allow for the precision necessary to complete the bonding operation. The expansion is causing the solder bumps to be placed under excessive force during the bonding operation, which results in their uncontrolled collapse upon melting, causing adjacent solder bumps to fuse to one another.

With die feature size growing ever smaller and the latest high-bump count dies pushing the limits of current thermo-compression bonding technologies, systems and methods which can achieve higher precision bonding have become necessary.

### SUMMARY OF THE INVENTION

One embodiment of the present invention discloses a system for thermo-compression bonding of high-bump count semiconductors, the system having a die head comprising a planar surface and a substrate head comprising a planar surface, wherein the planar surface of the substrate head is oriented to oppose the planar surface of the die head; wherein the planar surfaces of the die head and the substrate head are substantially parallel and capable of motion relative to one another in at least the axis perpendicular to their respective planar surfaces, such that they may be brought into compressing contact with one another; at least one force sensor configured to measure compressive forces between the substantially parallel planar surfaces of the die head and the substrate head during a bonding operation; a controller in communication with the force sensor and configured to continuously control the relative position of the substantially parallel planar surfaces of the die head and the substrate head during a bonding operation to maintain a desired compressive force, whereby thermal expansion of the die and substrate heads is continuously compensated for during a thermo-compression bonding operation.

Another embodiment of the present invention provides such a system for thermo-compression bonding of high-bump count semiconductors further comprising at least one distance measuring device in communication with the controller, wherein the at least one distance measuring device is used to measure the actual thermal expansion of the die and substrate heads perpendicularly to the parallel planar surfaces of the die and substrate heads, thereby supplementing the at least one force sensor and allowing for even finer compensation for thermal expansion of the die and substrate heads during a bonding operation.

A further embodiment of the present invention provides such a system for thermo-compression bonding of high-bump count semiconductors wherein the distance measuring device is selected from the group consisting of optical sensors, ultrasonic sensors, wire draw encoders, magnetic positioning sensors, optical linear measurement sensors, linear encoders, rotary encoders, capacitive encoders, inductive encoders, eddy current encoders and optical image sensors.

One embodiment of the present invention discloses a system for thermo-compression bonding of high-bump count semiconductors, the system having a die head comprising a planar surface and a substrate head comprising a planar surface, wherein the planar surface of the substrate head is oriented to oppose the planar surface of the die head; wherein the planar surfaces of the die head and the substrate head are substantially parallel and capable of motion relative to one another in at least the axis perpendicular to their respective planar surfaces, such that they may be brought into compressing contact with one another; at least one distance measuring device in communication with the controller configured to measure the thermal expansion of the die and substrate heads perpendicular to the parallel planar surfaces of the die and substrate heads during a bonding operation; and a controller in communication with the force sensor and configured to continuously control the relative position of the substantially parallel planar surfaces of the die head and the substrate head during a bonding operation to maintain a desired compressive force, whereby thermal expansion of the die and substrate heads is continuously compensated for during a thermo-compression bonding operation.

Another embodiment of the present invention provides such a system for thermo-compression bonding of high-bump count semiconductors wherein the distance measuring device is selected from the group consisting of optical sensors, ultrasonic sensors, wire draw encoders, magnetic positioning sensors, optical linear measurement sensors, linear encoders, rotary encoders, capacitive encoders, inductive encoders, eddy current encoders and optical image sensors.

One embodiment of the present invention provides a method for compensating for thermal expansion and contraction of die and substrate heads during a thermo-compression bonding operation comprising: providing a thermo-compression bonding system comprising: a die head comprising a planar surface; a substrate head comprising a planar surface, wherein the planar surface of the substrate head is oriented to oppose the planar surface of the die head; wherein the planar surfaces of the die head and the substrate head are substantially parallel and capable of motion relative to one another in at least the axis perpendicular to the planar surfaces, such that they may be brought into compressing contact with one another; at least one force sensor configured to measure compressive forces between the substantially parallel planar surfaces of the die head and the substrate head during a bonding operation; a controller in communication with the force sensor and configured to continuously control the relative position of the substantially parallel planar surfaces of the die head and the substrate head during a bonding operation to maintain a desired compressive force, whereby thermal expansion of the die and substrate heads is continuously compensated for during a thermo-compression bonding operation. placing a die to be bonded to a substrate on the planar surface of the die head, wherein a face of the die to be bonded to the substrate is positioned facing away from the planar surface of the die head; placing the substrate to be bonded to the die on the planar surface of the substrate head, wherein a face of the substrate to be bonded to the die is positioned facing away from the planar surface of the substrate head; moving the die head towards the substrate head until a desired compressive force is reached; heating the die and substrate heads to a desired temperature; continuously monitoring the compressive force perpendicular to the parallel planar faces of the die and substrate heads; adjusting the relative positions of the parallel planar faces of the die and substrate heads to maintain a substantially constant compressive force as the die and substrate heads expand and contract due to thermal stresses during a bonding operation; cooling the die and substrate heads; and removing the bonded die and substrate.

Another embodiment of the present invention provides such a method of compensating for thermal expansion and contraction of die and substrate heads during a thermo-compression bonding operation wherein the thermo-compression bonding system further comprises a distance measuring device in communication with the controller, wherein the step of continuously monitoring further comprises continuously monitoring the amount of thermal expansion of the die and substrate heads perpendicular to their planar faces via the distance measuring device and wherein the step of adjusting the relative positions of the parallel planar faces of the die and substrate heads comprises adjusting the relative positions of the parallel planar faces of the die and substrate heads to control for thermal expansion of the parallel planar faces of the die and substrate heads by adjusting their relative position as the die and substrate heads expand and contract due to thermal stresses, as indicated by the force sensor and the distance measuring device.

A further embodiment of the present invention provides such a method of compensating for thermal expansion and contraction of die and substrate heads during a thermo-compression bonding operation wherein the thermo-compression bonding system further comprises a distance measuring device in communication with the controller, in place of the force sensor, wherein the step of continuously monitoring further comprises continuously monitoring the amount of thermal expansion of the die and substrate heads perpendicular to their planar faces via the distance measuring device and wherein the step of adjusting the relative positions of the parallel planar faces of the die and substrate heads comprises adjusting the relative positions of the parallel planar faces of the die and substrate heads to control for thermal expansion of the parallel planar faces of the die and substrate heads by adjusting their relative position as the die and substrate heads expand and contract due to thermal stresses, as indicated by the distance measuring device.

Yet another embodiment of the present invention provides such a method for compensating for thermal expansion and contraction of die and substrate heads during a thermo-compression bonding operation wherein adjusting the relative positions of the parallel planar faces of the die and substrate heads maintains predefined compressive force profile, as opposed to a substantially constant force, during bonding as the die and substrate heads expand and contract due to thermal stresses.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1 is a top, left side perspective view of a thermo-compression bonding system configured in accordance with one embodiment of the present invention;

FIG. 2 is a front, right side perspective view of a gantry, a force applicator, a die bond head system and a substrate bond station, including various subsystems, in accordance with one embodiment of the present invention;

FIG. 3 is a front elevation view of a die head and a substrate head, the substrate head having a substrate positioned for bonding and the die head having a die positioned for bonding, the die head and substrate head being in uncompressed positions;

FIG. 4 is a front elevation view of a die head and a substrate head compressing a die and substrate; and

FIG. 5 is a front elevation view of a die head and a substrate head which has allowed for uncontrolled solder bump collapse, resulting in adjacent solder bumps making contact, causing the failure of the bonded die and substrate.

### DETAILED DESCRIPTION

Thermo-compression bonding is one method used to bond a die 302, also known as a chip, to a substrate 304. It is sometimes also referred to as diffusion bonding, pressure joining, thermo-compression welding or solid state welding. This process takes advantage of surface diffusion, grain boundary diffusion and bulk diffusion to physically and electrically connect a die 302 to a substrate 304, typically via solder bumps 306. Those skilled in the art, however, will appreciate that copper pillars, which are sometimes referred to as copper columns, micro-bumps with solder caps typically made of SnAg (although other alloys are possible) and other technologies can be used in place of solder bumps 306 in conjunction with the systems and methods described herein to achieve precision bonding of a die 302 to a substrate 304. When discussing solder bumps 306 in the remainder of this disclosure, it should be understood that what is being described is equally applicable to the aforementioned, and other, alternatives to solder bumps 306.

Solder bumps 306, or their alternatives, are applied during a previous processing step to the side of a die 302 to be bonded to a substrate 304. During thermo-compression bonding, these solder bumps 306 are first precisely aligned with corresponding bump pads 308 or other equivalent features of the substrate 304. Following alignment, heat and pressure are applied to complete the connection between the die 302 and substrate 304. In a thermo-compression bonding operation, a die head 110 and a substrate head 108, which are opposing parallel planar surfaces, are used to apply this heat and pressure to the die 302 and substrate 304.

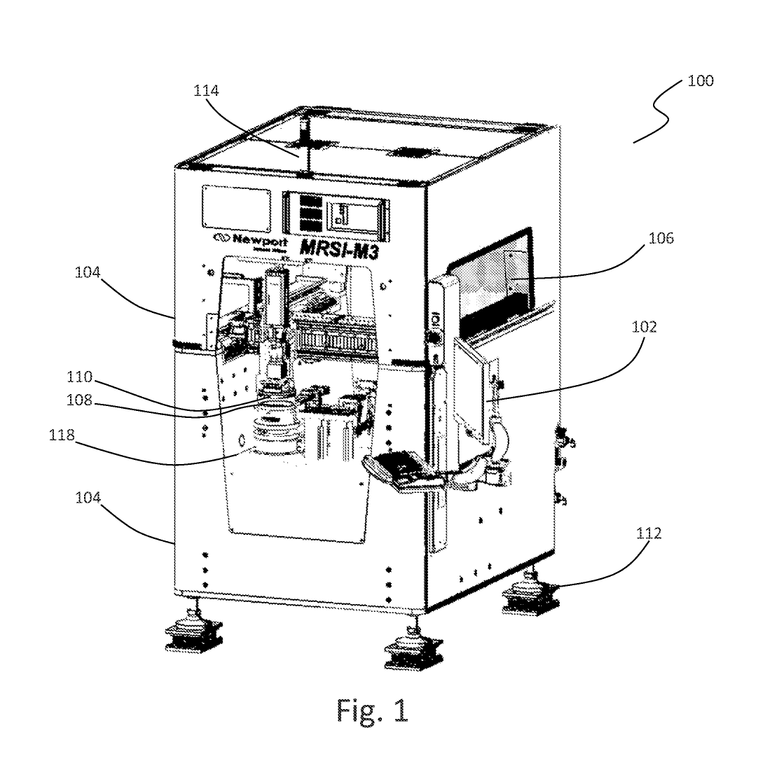

FIG. 1 depicts a thermo-compression bonding system 100 including a controller 102 in controlling communication with a substrate head 108 a die head 110, and an indicator 114 and in further communication with at least one force sensor (not shown) and at least one encoder (not shown), positioned to allow the thermal expansion of the die head 110 and/or substrate head 108 to be measured.

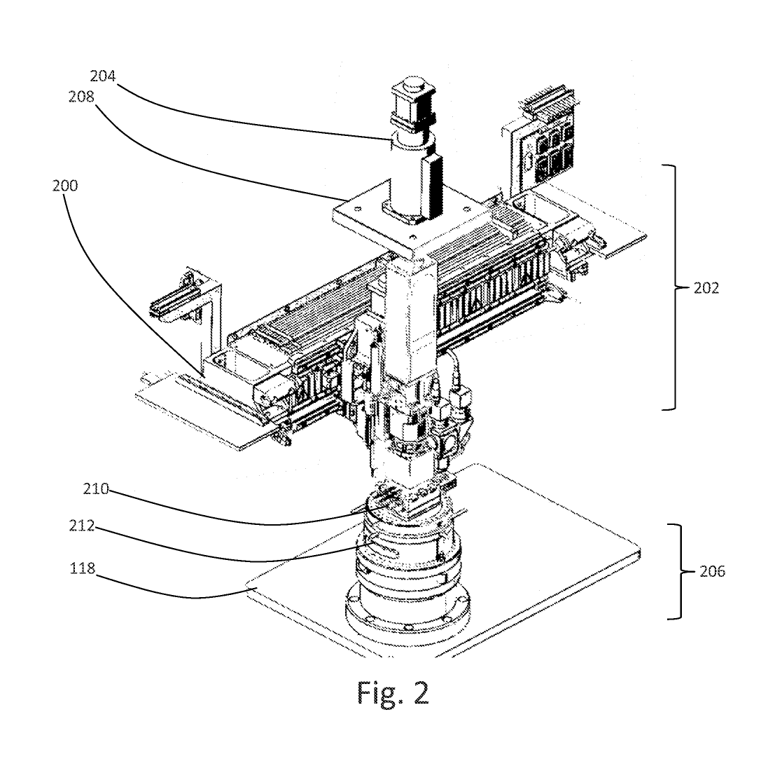

FIG. 2 depicts the thermo-compression bonding system 100 of FIG. 1, with body panels 104 and other ancillary equipment removed. From this view, a gantry 200 connected to the die bond head system 202, including the die head thermal control system body 210, which encompasses the die head 110, is visible. Also shown is a substrate bond station 206, including a substrate head thermal control system body 212, which encompasses the substrate head 108, attached to a supporting floor 118. Another element of this system is the force applicator 204, which is fixed to a support member 208. It will be apparent to those of ordinary skill in the art that many variations to this general setup are possible. For instance, rather than applying a compressive force through a force applicator 204, the gantry 200 itself or other force applying means could supply the compressive force. In other cases, the die head 110 and substrate head 108 may be kept stationary while a die 302 and substrate 304 are brought to them via a conveyor belt, robotic grasping equipment or other means.

Now referring to FIGS. 1 and 2, the arrangement of the aforementioned elements allows for the die head 110, controlled by the controller 102, via the gantry 200, to be positioned directly over the substrate head 108 in preparation for a thermo-compression bonding operation. The controller 102 also controls heating and cooling systems contained within or adjacent to both the substrate head 108 and the die head 110. Furthermore, the controller 102 is in communication, in this embodiment, with a force applicator 204, which is fixed to a support member 208. The force applicator 204 is used to apply compressive forces to the die head 110, while the substrate head 108 is supported by the supporting floor 118, allowing the applied force to act upon the solder bumps 306 between the die 302 and substrate 304. During compression of the die 302 and substrate 304, heat is applied via a die head thermal control system body 210 and a substrate head thermal control system body 212. It will be apparent to one of ordinary skill in the art that there are a number of ways to position a die 302 and substrate 304 for thermo-compression bonding and to apply heat and force to these components after positioning.

The controller 102 is configured to receive data regarding the compressive force applied to a die 302 and a substrate 304 positioned between the die head 110 and substrate head 108 from at least one force sensor (not shown), which may be positioned on the die head 110, the substrate head 108, or may indirectly measure the forces in a number of alternative ways. Some exemplary force sensors are strain gauge load cells, such as semiconductor gauges, thin film gauges and foil gauges, piezoelectric crystal force sensors, hydraulic force sensors, pneumatic force sensors, LVDT sensors, capacitive sensors, tuning fork sensors, vibrating wire sensors, magnetorestrictive sensors, gyroscopic sensors and force balance sensors, although alternative means of measuring force will be apparent to one of ordinary skill in the art.

The controller 102 is also configured to modulate the compressive forces applied to the die 302 and substrate 304 during thermo-compression bonding, taking into account measurements from at least one of the force sensors and/or encoders. In a typical bonding process, the force desired to be applied may be constant or vary during the bonding operation. The measurements taken from the force sensor(s) and/or encoder(s) are used to alter the desired force profile to compensate for thermal expansion and contraction of portions of the thermo-compression bonding system 100, particularly that of the die head 110, as the expansion of this part of the thermo-compression bonding system 100 tends to be most pronounced, due to the high heat and significant temperature variations encountered during a typical thermo-compression bonding operation.

The controller 102 may also be configured to communicate process stage, alarm conditions, warnings and other pertinent information via the indicator 114, typically by varying the indicator 114 color, intensity or causing it to blink, typically in a series of short and long blinks to convey specific information. The thermo-compression bonding system also includes body panels 104, material passages 106, isolating supports 112, a die head 110 movement mechanism (a gantry 200 is shown, but a number of alternative systems for positioning a die 302 and substrate 304 between the die head 110 and the substrate head 108 will be apparent to one of ordinary skill in the art).

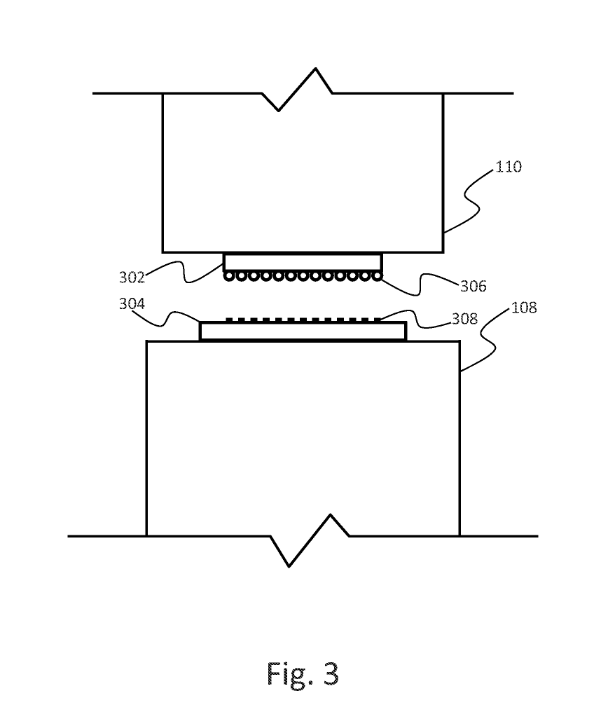

Now referring to FIG. 3, a front elevation view of the die head 110 and the substrate head 108 is shown. In this view, a substrate 304 with bump pads 308 is shown positioned on the substrate head 108 and a die 302 with solder bumps 306 is shown positioned on the die head 110 in preparation for a thermo-compression bonding operation. The die head 110 and substrate head 108 are shown in an uncompressed position. Also, the solder bumps 306 shown are round and relatively large in relation to the die 110, however they are not drawn to scale and are used only to illustrate the general concept. In a typical thermo-compression bonding operation, these solder bumps 306 may be any variety of shapes and are typically smaller than 100 μm and number in the thousands per die 302. There are a number of ways that would be apparent to one of ordinary skill in the art for precisely holding a die 302 and substrate 304 to the die head 110 and substrate head 108, respectively, such as by vacuum. Alternatively, dies 302 and substrates 304 may be brought to a stationary bonding station having a die head 110 and a substrate head 108 without altering the inventive concept disclosed herein.

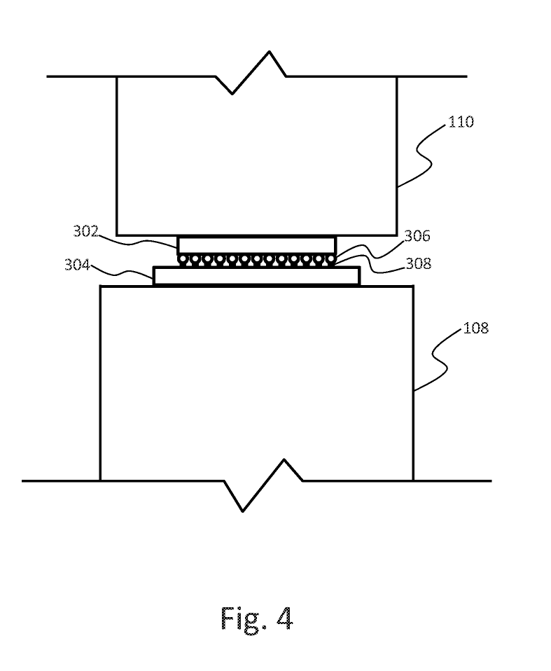

FIG. 4 shows the die head 110 and substrate head 108 of FIG. 3, in a compressed state during a normal thermo-compression bonding operation. As shown, heat and compressive forces are being applied to the die 302 and solder bumps 306 via the die head 110, while the substrate 304 and bump pads 308 are held stationary by the substrate head 108.

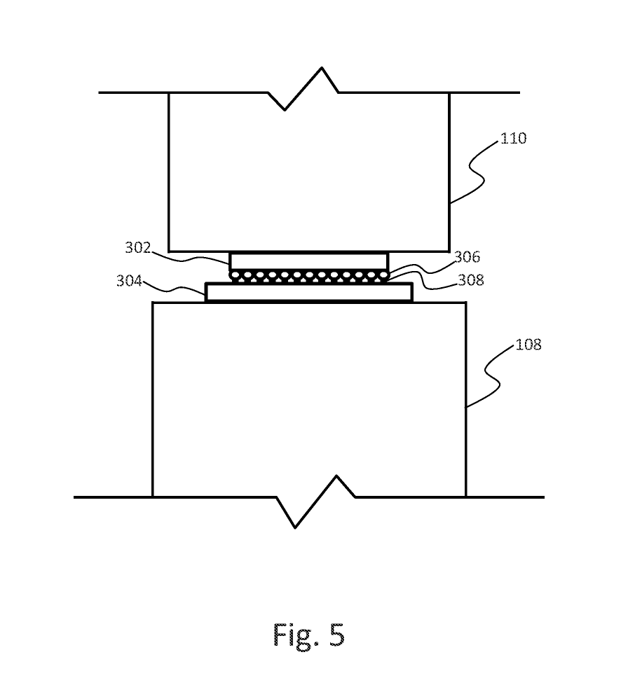

FIG. 5 shows the die head 110 and substrate head 108 of FIG. 3, immediately after uncontrolled solder bump 306 collapse has occurred. Although each solder bump 306 is expected to flow and deform as a natural and necessary consequence of the bonding operation, excess deformation and flow, as shown here, will cause adjacent solder bumps 306 to contact one another, preventing normal operation of the die 302 and substrate 304 while simultaneously increasing the difficulty of and sometimes even preventing the subsequent processing step of under-filing, or filling of the void between die 302 and substrate 304 with a resin. This uncontrolled collapse of solder bumps 306 is caused by the expansion of portions of the thermo-compression bonding system 100, such as the die head 110, exerting additional pressure on the solder bumps 306 due to thermal expansion, followed by the expected flow of solder bumps 306 after a critical temperature is met. Since there is an excess of force, the solder bumps 306 will collapse to a greater degree than is desired, causing failure of the bonding operation.

To prevent the uncontrolled collapse of solder bumps 306, monitoring of the thermal expansion, as measured via an encoder or inferred from force sensor readings, as compared to an expected or known applied force during a process stage and alteration of at least the applied compressive force or the position of either the die head 110 or substrate head 108 is necessary to achieve consistent bonding due to the precision demanded to effectively bond the latest generation of chips using thermo-compression bonding techniques.

In embodiments, the thermo-compression bonding system 100 includes a die head 110 comprising a planar surface and a substrate head 108 comprising a planar surface, wherein the planar surface of the substrate head 108 is oriented to oppose the planar surface of the die head 110; wherein the planar surfaces of the die head 110 and the substrate head 108 are substantially parallel and capable of motion relative to one another in at least the axis perpendicular to the planar surfaces, such that they may be brought into compressing contact with one another; at least one force sensor configured to measure compressive forces between the substantially parallel planar surfaces of the die head 110 and the substrate head 108 during a bonding operation; a controller 102 in communication with the force sensor and configured to continuously control the relative position of the substantially parallel planar surfaces of the die head 110 and the substrate head 108 during a bonding operation to maintain a desired compressive force, whereby thermal expansion of the die head 110 and substrate head 108 is continuously compensated for during a thermo-compression bonding operation.

In other embodiments, a distance measuring device in communication with the controller 102 may be used to measure the actual thermal expansion of the die head 110 and substrate head 108 perpendicular to the parallel planar surfaces of the die head 110 and substrate head 108, thereby supplementing the at least one force sensor and allowing for even finer compensation for thermal expansion of the die head 110 and substrate head 108 during a bonding operation. In additional embodiments, at least one distance sensor may be employed without the aid of force sensors to similar effect as the previously described combination. The distance measuring devices used in such embodiments may be optical sensors, ultrasonic sensors, wire draw encoders, magnetic positioning sensors, optical linear measurement sensors, linear encoders, rotary encoders, capacitive encoders, inductive encoders, eddy current encoders, optical image sensors and a variety of similar sensors with which one skilled in the art will be familiar.

One embodiment of the present invention provides a method for compensating for thermal expansion and contraction of a die head 110 and a substrate head 108 during a thermo-compression bonding operation comprising: providing a thermo-compression bonding system 100 comprising: a die head 110 comprising a planar surface; a substrate head 108 comprising a planar surface, wherein the planar surface of the substrate head 108 is oriented to oppose the planar surface of the die head 110; wherein the planar surfaces of the die head 110 and the substrate head 108 are substantially parallel and capable of motion relative to one another in at least the axis perpendicular to the planar surfaces, such that they may be brought into compressing contact with one another; at least one force sensor configured to measure compressive forces between the substantially parallel planar surfaces of the die head 110 and the substrate head 108 during a bonding operation; a controller 102 in communication with the force sensor and configured to continuously control the relative position of the substantially parallel planar surfaces of the die head 110 and the substrate head 108 during a bonding operation to maintain a desired compressive force, whereby thermal expansion of the die head 110 and substrate head 108 is continuously compensated for during a thermo-compression bonding operation. placing a die 302 to be bonded to a substrate 304 on the planar surface of the die head 110, wherein a face of the die 302 to be bonded to the substrate 304 is positioned facing away from the planar surface of the die head 110; placing the substrate 304 to be bonded to the die 302 on the planar surface of the substrate head 108, wherein a face of the substrate 304 to be bonded to the die 302 is positioned facing away from the planar surface of the substrate head 108; moving the die head 110 towards the substrate head 108 until a desired compressive force is reached; heating the die head 110 and substrate head 108 to a desired temperature; continuously monitoring the compressive force perpendicular to the parallel planar faces of the die head 110 and substrate head 108; adjusting the relative positions of the parallel planar faces of the die head 110 and substrate head 108 to maintain a substantially constant compressive force as the die head 110 and substrate head 108 expand and contract due to thermal stresses during a bonding operation; and removing the bonded die 302 and substrate 304.

In additional embodiments, a distance measuring device in communication with the controller 102 is included, wherein the step of continuously monitoring further comprises continuously monitoring the amount of thermal expansion of the die head 110 and substrate head 108 perpendicular to their planar faces via the distance measuring device and wherein the step of adjusting the relative positions of the parallel planar faces of the die head 110 and substrate head 108 comprises adjusting the relative positions of the parallel planar faces of the die head 110 and substrate head 108 to control for thermal expansion of the parallel planar faces of the die head 110 and substrate head 108 by adjusting their relative position as the die head 110 and substrate head 108 expand and contract due to thermal stresses, as indicated by the force sensor and the distance measuring device.

A further embodiment of the present invention provides such a method of compensating for thermal expansion and contraction of the die head 110 and substrate head 108 during a thermo-compression bonding operation wherein the thermo-compression bonding system 100 comprises a distance measuring device in communication with the controller 102, in place of the force sensor, wherein the step of continuously monitoring further comprises continuously monitoring the amount of thermal expansion of the die head 110 and substrate head 108 perpendicular to their planar faces via the distance measuring device and wherein the step of adjusting the relative positions of the parallel planar faces of the die head 110 and substrate head 108 comprises adjusting the relative positions of the parallel planar faces of the die head 110 and substrate head 108 to control for thermal expansion of the parallel planar faces of the die head 110 and substrate head 108 by adjusting their relative position as the die head 110 and substrate head 108 expand and contract due to thermal stresses, as indicated by the distance measuring device.

Yet another embodiment of the present invention provides such a method for compensating for thermal expansion and contraction of the die head 110 and substrate head 108 during a thermo-compression bonding operation wherein adjusting the relative positions of the parallel planar faces of the die head 110 and substrate head 108 maintains a predefined compressive force profile, as opposed to a substantially constant force, during bonding as the die head 110 and substrate head 108 expand and contract due to thermal stresses.

The foregoing description of the embodiments of the invention has been presented for the purposes of illustration and description. Each and every page of this submission, and all contents thereon, however characterized, identified, or numbered, is considered a substantive part of this application for all purposes, irrespective of form or placement within the application. This specification is not intended to be exhaustive or to limit the invention to the precise form disclosed. Many modifications and variations are possible in light of this disclosure.

What is claimed is:

1. A system for thermo-compression bonding of high-bump count semiconductors, the system comprising:
a die head comprising a planar surface;
a substrate head comprising a planar surface, wherein said planar surface of said substrate head is oriented to oppose said planar surface of said die head;
wherein said planar surfaces of said die head and said substrate head are substantially parallel and capable of motion relative to one another in at least the axis perpendicular to their respective planar surfaces, such that they may be brought into compressing contact with one another;
at least one force sensor configured to measure compressive forces between said substantially parallel planar surfaces of said die head and said substrate head during a bonding operation; and
a controller in communication with said force sensor configured to continuously control the relative position of said substantially parallel planar surfaces of said die head and said substrate head during a bonding operation to maintain a desired compressive force, whereby thermal expansion of said die and substrate heads is continuously compensated for during a thermo-compression bonding operation.

2. The system for thermo-compression bonding of high-bump count semiconductors of claim 1 further comprising at least one distance measuring device in communication with said controller, wherein the at least one distance measuring device is used to measure the actual thermal expansion of said die and substrate heads perpendicularly to said parallel planar surfaces of said die and substrate heads, thereby supplementing said at least one force sensor and allowing for even finer compensation for thermal expansion of said die and substrate heads during a bonding operation.

3. The system for thermo-compression bonding of high-bump count semiconductors of claim 2 wherein said distance measuring device is selected from the group consisting of optical sensors, ultrasonic sensors, wire draw encoders, magnetic positioning sensors, optical linear measurement sensors, linear encoders, rotary encoders, capacitive encoders, inductive encoders, eddy current encoders and optical image sensors.

4. A system for thermo-compression bonding of high-bump count semiconductors, the system comprising:
a die head comprising a planar surface;
a substrate head comprising a planar surface, wherein said planar surface of said substrate head is oriented to oppose said planar surface of said die head;
wherein said planar surfaces of said die head and said substrate head are substantially parallel and capable of motion relative to one another in at least the axis perpendicular to their respective planar surfaces, such that they may be brought into compressing contact with one another;
at least one distance measuring device in communication with said controller configured to measure the thermal expansion of said die and substrate heads perpendicular to said parallel planar surfaces of said die and substrate heads during a bonding operation; and
a controller in communication with said distance measuring device configured to continuously control the relative position of said substantially parallel planar surfaces of said die head and said substrate head during a bonding operation to maintain a desired compressive force, whereby thermal expansion of said die and substrate heads is continuously compensated for during a thermo-compression bonding operation.

5. The system for thermo-compression bonding of high-bump count semiconductors of claim 4 wherein said distance measuring device is selected from the group consisting of optical sensors, ultrasonic sensors, wire draw encoders, magnetic positioning sensors, optical linear measurement sensors, linear encoders, rotary encoders, capacitive encoders, inductive encoders, eddy current encoders and optical image sensors.

6. A method for compensating for thermal expansion and contraction of die and substrate heads during a thermo-compression bonding operation comprising:
providing a thermo-compression bonding system comprising:
a die head comprising a planar surface;
a substrate head comprising a planar surface, wherein said planar surface of said substrate head is oriented to oppose said planar surface of said die head;
wherein said planar surfaces of said die head and said substrate head are substantially parallel and capable of motion relative to one another in at least the axis perpendicular to said planar surfaces, such that they may be brought into compressing contact with one another;
at least one force sensor configured to measure compressive forces between said substantially parallel planar surfaces of said die head and said substrate head during a bonding operation; and
a controller in communication with said force sensor and configured to continuously control the relative position of said substantially parallel planar surfaces of said die head and said substrate head during a bonding operation to maintain a desired compressive force, whereby thermal expansion of said die and substrate heads is continuously compensated for during a thermo-compression bonding operation;
placing a die to be bonded to a substrate on said planar surface of said die head, wherein a face of said die to be bonded to said substrate is positioned facing away from said planar surface of said die head;
placing said substrate to be bonded to said die on said planar surface of said substrate head, wherein a face of said substrate to be bonded to said die is positioned facing away from said planar surface of said substrate head;
moving said die head towards said substrate head until a desired compressive force is reached;
heating said die and substrate heads to a desired temperature;
substantially continuously monitoring said compressive force perpendicular to said parallel planar faces of said die and substrate heads;
adjusting the relative positions of said parallel planar faces of said die and substrate heads to maintain a substantially constant compressive force as said die and substrate heads expand and contract due to thermal stresses during a bonding operation;
cooling said die and substrate heads; and
removing the bonded die and substrate.

7. The method of compensating for thermal expansion and contraction of die and substrate heads during a thermo-compression bonding operation of claim 6 wherein said thermo-compression bonding system further comprises a distance measuring device in communication with said controller, wherein the step of continuously monitoring further comprises continuously monitoring the amount of thermal expansion of the die and substrate heads perpendicular to their planar faces via the distance measuring device and wherein the step of adjusting the relative positions of said parallel planar faces of said die and substrate heads comprises adjusting the relative positions of said parallel planar faces of said die and substrate heads to control for thermal expansion of said parallel planar faces of said die and substrate heads by adjusting their relative position as said die and substrate heads expand and contract due to thermal stresses, as indicated by said force sensor and said distance measuring device.

8. The method of compensating for thermal expansion and contraction of die and substrate heads during a thermo-compression bonding operation of claim 6 wherein said thermo-compression bonding system comprises a distance measuring device in communication with said controller, in place of said force sensor, wherein the step of continuously monitoring further comprises continuously monitoring the amount of thermal expansion of the die and substrate heads perpendicular to their planar faces via the distance measuring device and wherein the step of adjusting the relative positions of said parallel planar faces of said die and substrate heads comprises adjusting the relative positions of said parallel planar faces of said die and substrate heads to control for thermal expansion of said parallel planar faces of said die and substrate heads by adjusting their relative position as said die and substrate heads expand and contract due to thermal stresses, as indicated by said distance measuring device.

9. The method of compensating for thermal expansion and contraction of die and substrate heads during a thermo-compression bonding operation of claim 6 wherein adjusting the relative positions of said parallel planar faces of said die and substrate heads maintains a predefined compressive force profile, as opposed to a substantially constant force, during bonding as said die and substrate heads expand and contract due to thermal stresses.
